(19) United States
(12) Patent Application Publication
(10) Pub. No.: US 2025/0132121 A1
(43) Pub. Date: Apr. 24, 2025

(54) METHOD OF OPERATING A CHARGED PARTICLE BEAM APPARATUS, AND CHARGED PARTICLE BEAM APPARATUS

(71) Applicant: ICT Integrated Circuit Testing Gesellschaft für Halbleiterprüftechnik mbH, Heimstetten (DE)

(72) Inventors: Stanislav Bardy, München (DE); Pavel Adamec, Haar (DE)

(73) Assignee: ICT Integrated Circuit Testing Gesellschaft für Halbleiterprüftechnik mbH, Heimstetten (DE)

(21) Appl. No.: 18/382,263

(22) Filed: Oct. 20, 2023

(51) Int. Cl. H01J 37/21; H01J 37/141; H01J 37/147; H01J 37/244; H01J 37/28

(52) U.S. Cl. CPC H01J 37/21; H01J 37/141; H01J 37/1477; H01J 37/244; H01J 37/28

(57) ABSTRACT

A method of operating a charged particle beam apparatus is described. The method includes guiding a primary charged particle beam through an opening of an on-axis detector, through an intermediate lens, through an objective lens, and onto a specimen, wherein the intermediate lens is disposed between the on-axis detector and the objective lens; focusing the primary charged particle beam with the objective lens onto the specimen; in a first mode of operation, providing an excitation of the intermediate lens to collimate high energy signal electrons including backscattered electrons to the opening of the on-axis detector; in the first mode of operation, detecting low energy signal electrons including secondary electrons with the on-axis detector; and in the first mode of operation, detecting the backscattered electrons with a second electron detector upstream of the on-axis detector. Also a corresponding charged particle beam apparatus is described.

### TECHNICAL FIELD

Embodiments described herein relate to one or more lenses for a charged particle beam in a charged particle beam apparatus, for example in an electron microscope, particularly in a scanning electron microscope (SEM). Further, embodiments of the present disclosure relate to an intermediate lens and an objective lens and a method of operating a charged particle beam apparatus, particularly including energy filtering. Specifically, embodiments relate to a method of operating a charged particle beam apparatus and a charged particle beam apparatus.

### BACKGROUND

Modern semiconductor technology has created a high demand for structuring and probing samples in the nanometer or even in the sub-nanometer scale. Micrometer and nanometer-scale process control, inspection or structuring, is often done with charged particle beams, e.g. electron beams, which are generated, shaped, deflected and focused in charged particle beam apparatuses, such as electron microscopes or electron beam pattern generators. For inspection purposes, charged particle beams offer a superior spatial resolution compared to, e.g., photon beams.

Apparatuses using charged particle beams, such as scanning electron microscopes (SEM), have many functions in a plurality of industrial fields, including, but not limited to, inspection of electronic circuits, exposure systems for lithography, detecting systems, defect inspection tools, and testing systems for integrated circuits. In such particle beam systems, fine beam probes with a high current density can be used. For instance, in the case of an SEM, the primary electron beam generates signal particles like secondary electrons (SE) and/or backscattered electrons (BSE) that can be used to image and/or inspect a sample.

Reliably inspecting and/or imaging samples with a charged particle beam apparatus at a good resolution is, however, challenging. Further, particularly in the semiconductor industry, throughput, for example, for image generation, is beneficially high. The throughput can be increased by increasing the signal-to-noise ratio of the signal electrons. For example, the collection efficiency for the signal electrons can be increased.

Further, the measurements can be improved by additional detection modes to increase the amount of information that can be determined based on the measurement of e.g. a semiconductor wafer or another sample.

In light of the above, providing an improved method of operating a charged particle beam apparatus and an improved charged particle beam apparatus are beneficial.

### SUMMARY

In light of the above, a method of operating a charged particle beam apparatus and a charged particle beam apparatus are provided according to the independent claims. Further advantages, features, aspects and details that can be combined with embodiments described herein are evident from the dependent claims, the description and the drawings.

According to an embodiment, a method of operating a charged particle beam apparatus is provided. The method includes guiding a primary charged particle beam through an opening of an on-axis detector, through an intermediate lens, through an objective lens, and onto a specimen, wherein the intermediate lens is disposed between the on-axis detector and the objective lens; focusing the primary charged particle beam with the objective lens onto the specimen; in a first mode of operation, providing an excitation of the intermediate lens to collimate high energy signal electrons including backscattered electrons to the opening of the on-axis detector; in the first mode of operation, detecting low energy signal electrons including secondary electrons with the on-axis detector; and in the first mode of operation, detecting the backscattered electrons with a second electron detector upstream of the on-axis detector.

According to an embodiment, a charged particle beam apparatus is provided. The charged particle beam apparatus includes a charged particle beam source configured to generate a primary charged particle beam; beam guiding optics configured to guide the primary charged particle beam towards a specimen stage; an on-axis detector having an opening configured for trespassing of the primary charged particle beam; a second detector upstream of the on-axis detector; an intermediate lens disposed between the on-axis detector and the specimen stage and configured to collimate high energy signal electrons on the opening of the on-axis detector; an objective lens disposed between the intermediate lens and the specimen stage, and an energy filter along a signal beam path between the opening of the on-axis detector and the second detector.

According to an embodiment, a charged particle beam apparatus is provided. The charged particle beam apparatus includes a charged particle beam source configured to generate a primary charged particle beam; beam guiding optics configured to guide the primary charged particle beam towards a specimen stage; an on-axis detector having an opening configured for trespassing of the primary charged particle beam; a second detector upstream of the on-axis detector; an intermediate lens disposed between the on-axis detector and the specimen stage and configured to collimate high energy signal electrons on the opening of the on-axis detector; an objective lens disposed between the intermediate lens and the specimen stage, and a controller with a processor and a memory storing instructions that, when executed by the processor, cause the charged particle beam apparatus to perform a method according to any of the embodiments described herein.

### BRIEF DESCRIPTION OF THE DRAWINGS

So that the manner in which the above recited features of the present disclosure can be understood in detail, a more particular description, briefly summarized above, may be had by reference to embodiments. The accompanying drawings relate to one or more embodiments and are described in the following.

FIG. 1 shows a schematic view of a charged particle apparatus according to embodiments described herein.

FIG. 2 shows a portion of a charged particle beam apparatus, in particular an intermediate lens, an objective lens, and an on-axis detector to describe embodiments according to the present disclosure.

FIG. 3 shows a flow chart illustrating a method of operating a charged particle beam apparatus according to embodiments described herein.

FIG. 4 shows a comparison of graphs without and with operation of an intermediate lens according to embodiments of the present disclosure.

FIGS. 5A and 5B shows a comparison of the first mode of operation and the second mode of operation according to embodiments of the present disclosure.

FIG. 6 shows a method of operating a charged particle beam apparatus according to a second mode of operation.

### DETAILED DESCRIPTION

Reference will now be made in detail to the various embodiments, one or more examples of which are illustrated in the figures. Within the following description of the drawings, same reference numbers refer to same components. Generally, only the differences with respect to individual embodiments are described. Each example is provided by way of explanation and is not meant as a limitation. Further, features illustrated or described as part of one embodiment can be used on or in conjunction with other embodiments to yield yet a further embodiment. It is intended that the description includes such modifications and variations.

Embodiments of the present disclosure provide an intermediate lens between an on-axis detector and an objective lens, particularly a combined electrostatic magnetic objective lens, to e.g. improve the detection efficiency of backscattered electrons (BSE), i.e. high energetic signal electrons. Additionally or alternatively, different modes of operation can be provided for energy filtering of signal electrons.

According to an embodiment, a method of operating a charged particle beam apparatus is provided. The method includes guiding a primary charged particle beam through an opening of an on-axis detector, through an intermediate lens, through an objective lens and onto a specimen wherein the intermediate lens is disposed between the on-axis detector and the objective lens. The method includes focusing the charged particle beam with the objective lens onto the specimen. In a first mode of operation, the intermediate lens is excited to collimate high energy signal electrons including backscattered electrons to the opening of the on-axis detector. Further, in the first mode of operation, low energy signal electrons including secondary electrons are detected with the on-axis detector and backscattered electrons are detected with the second electron detector upstream of the on-axis detector.

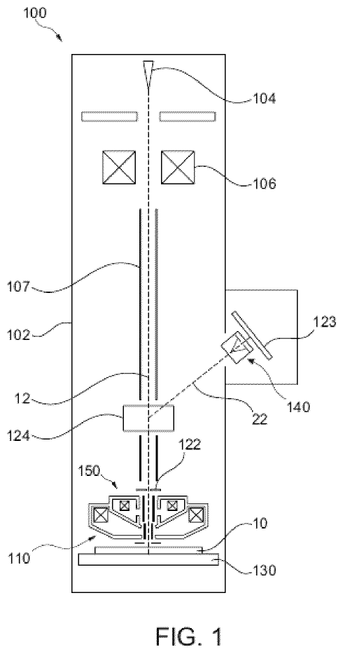

FIG. 1 is a schematic view of a charged particle beam apparatus 100 for inspecting and/or imaging a sample 10 or portions of a sample according to embodiments described herein. The charged particle beam apparatus 100 includes a column 102. The column 102 can provide a vacuum enclosure such that the charged particle beam travels under vacuum. The beam-optical components of the charged particle beam apparatus 100 can be placed in a vacuum chamber of the column 102 that can be evacuated. A vacuum can be beneficial for propagation of the charged particle beam, for example, along the optical axis 12 from the charged particle beam source 104 toward the sample stage 130. The charged particle beam may hit the sample under a sub-atmospheric pressure, e.g. a pressure below 10⁻³mbar or a pressure below 10⁻⁵ mbar.

The charged particle beam apparatus 100 includes a charged particle beam source 104. A charged particle beam source can be configured to emit a charged particle beam. The charged particle beam may be an electron beam. The charged particle beam may propagate along an optical axis 12. The charged particle beam apparatus 100 further includes a sample stage 130. An objective lens 110 focuses the charged particle beam, i.e., a primary charged particle beam, on the sample 10. The sample can be placed on the sample stage 130.

A condenser lens 106 or a condenser lens system including one or more condenser lenses may be arranged downstream of the charged particle beam source 104. The condenser lens system can collimate the charged particle beam propagating toward the objective lens 110. Further, an electrode or tube 107 configured to accelerate the beam can be provided. The electrode or tube can be provided on a high potential. The high potential can, for example, be a high positive potential relative to the charged particle beam source to accelerate an electron beam.

According to some embodiments, which can be combined with other embodiments described herein, a charged particle beam apparatus may include a condenser lens or a condenser lens system, particularly a condenser lens or a condenser lens system between a charged particle beam source 104 and a detector (downstream of the condenser lens).

The electrode or tube 107 may provide an acceleration section for accelerating the electron beam, e.g., to an electron energy of 5 keV or more. The electrons may be first accelerated by an extractor electrode that is set on a positive potential relative to an emission tip of the charged particle beam source 104. The electrode or tube may provide for further beam acceleration. In some embodiments, the charged particles, for example, electrons, are accelerated to an electron energy of 10 keV or more, 30 keV or more, or even 50 keV or more. A high electron energy within the column can reduce negative effects of electron-electron interactions. A high beam energy within the charged particle beam apparatus can improve an imaging resolution.

The charged particle beam apparatus 100 further includes two or more charged particle detectors, particularly two or more electron detectors. According to embodiments described herein, an on-axis detector 122 is provided. Further, a second electron detector is provided. For example, the second electron detector can be an off-axis detector 123. The on-axis detector and the second electron detector can detect signal particles emitted or released from the sample 10. The signal electrons are emitted or released from the sample upon impingement of the primary charged particle beam on the sample. According to different modes of operation, the charged particle detectors can each detect high energy signal electrons or low energy signal electrons. For example, high energy signal electrons can be backscattered electrons and low energy signal electrons can be secondary electrons. According to different modes of operation, filtering of signal electrons depending on the energy of the signal electrons can be provided.

FIG. 1 shows an energy filter 140. Embodiments of the present disclosure include an intermediate lens. The intermediate lens is configured to guide the signal electrons towards an opening of an on-axis detector or towards the second electron detector upstream of the on-axis detector. Signal losses can be reduced. Particularly for high energy signal electrons, for example, backscattered signal electrons, signal losses may occur, e.g. depending on the starting angle. As described herein, the backscattered electrons may have energies of 1 keV or above and even 10 keV or above. Having an increased detection efficiency for high energy signal electrons improves the utilization of an energy filter, particularly for the high energy signal electrons. Accordingly, embodiments of the present disclosure, which can be combined with other embodiments described herein, can include the energy filter 140. The energy filter 140 can be provided along a signal beam path between the opening of the on-axis detector and the second electron detector upstream of the on-axis detector. According to some embodiments, which can be combined with other embodiments described herein, the energy filter 140 can be configured to provide a bandpass filter. The energy filter can be a bandpass filter.

For example, a dispersive element like an electrostatic sector or a magnetic sector (or magnetic prism), e.g. a hemispherical energy analyzer, can be provided. According to some embodiments, which can be combined with other embodiments described herein, the energy filter may include spherical electrodes or curved electrodes, particularly a pair of spherical electrodes or curved electrodes. The dispersive element deflects signal electrons depending on their energy, which enables selection of an energy range by, for example, a slit opening, or an aperture having an opening, in general. According to some embodiments, which can be combined with other embodiments described herein, a dispersive element may also include a Wien filter element having a magnetic field and an electrostatic field perpendicular to each other. Also more complex energy filters like an omega-filter may be utilized.

According to some embodiments, which can be combined with other embodiments described herein, a beam separator 124 can be provided. Particularly for a charged particle beam apparatus including an off-axis detector, the signal charged particle beam 22 can be separated from the primary charged particle beam traveling along the optical axis 12. The beam separator 124 can include a magnetic deflector, wherein the beam deflection of the signal charged particle beam 22 results from the signal charged particle beam traveling in the opposite direction as compared to the primary charged particle beam.

An image generation unit (not shown) may be provided. The image generation unit can be configured to generate one or more images of the sample 10. The image generation unit can generate the one or more images based on the signal received from the detectors. The image generation unit can forward the one or more images of the sample to a processing unit (not shown).

The sample stage 130 may be a movable stage. In particular, the sample stage 130 may be movable in the Z-direction, i.e., in the direction of the optical axis 12, such that the distance between the objective lens 110 and the sample stage 130 can be adjusted. By moving the sample stage 130 in the Z-direction, the sample 10 can be moved to different “working distances”. Further, the sample stage 130 may also be movable in a plane perpendicular to the optical axis 12 (also referred to herein as the X-Y-plane). By moving the sample stage 130 in the X-Y-plane, a specified surface region of the sample 10 can be moved into an area, e.g. a field of view (FOV), below the objective lens 110, such that the specified surface region can be imaged by focusing the charged particle beam on the surface region of the sample.

For example, the charged particle beam apparatus 100 may be an electron microscope, particularly a scanning electron microscope. According to some embodiments, which can be combined with other embodiments described herein, a scan deflector (not shown) may be provided for scanning the charged particle beam, particularly over a surface of the sample 10 along a predetermined scanning pattern, for example, in the X-direction and/or in the Y-direction.

One or more surface regions of the sample 10 can be inspected and/or imaged with the charged particle beam apparatus 100. The term “sample” as used herein may also be referred to as the “specimen” and may relate to a substrate, for example, with one or more layers or features formed thereon, a semiconductor wafer, a glass substrate, a flexible substrate, such as a web substrate, or another sample that is to be inspected. The sample can be inspected for one or more of (1) imaging a surface of the sample, (2) measuring dimensions of one or more features of the sample, e.g. in a lateral direction, i.e. in the X-Y-plane, (3) conducting critical dimension measurements and/or metrology, (4) detecting defects, and/or (5) investigating the quality of the sample.

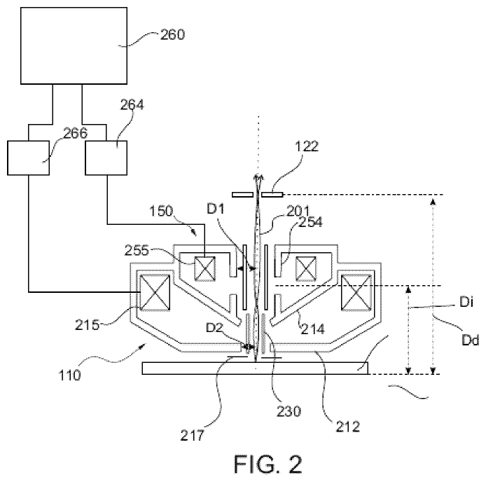

According to embodiments of the present disclosure, the charged particle beam apparatus 100 includes an intermediate lens 150. The intermediate lens 150, the on-axis detector 122, and the objective lens 110, as well as the operation of the components are described in more detail with respect to FIG. 2. Backscattered electrons (BSEs), such as high energetic backscattered electrons having high polar angles are difficult to get inside the column where the signal electrons can be detected and/or filtered. Due to the spherical aberration of the objective lens 110, e.g. the high polar angle BSE are strongly focused and may hit the funnel 230 before the signal electrons reach a detector. Accordingly, the detection efficiency is reduced by losing the signal electrons. According to embodiments of the present disclosure, an intermediate lens 150 is provided. The intermediate lens (IML), or intermediate magnetic lens, decreases the divergence of the BSE beam. Accordingly, the BSEs can be collimated to the opening of the on-axis detector 122 and can be detected e.g. by the second electron detector, such as off-axis detector 123. The increased collections efficiency increases the throughput. This is indicated by the BSE beam 201 show in FIG. 2. According to embodiments of the present disclosure, the intermediate lens can control the BSEs and/or may be used for energy filtering as described below.

FIG. 2 illustrates the intermediate lens 150 and the objective lens 110. The objective lens 110 can be a magnetic lens or particularly a combined electrostatic-magnetic lens. The objective lens 110 when having a magnetic component includes a coil 215, a lower pole piece 212 and an upper pole piece 214. Further, an electrode 217 can be provided to form a lens together with another element on a higher potential upstream of the electrode 217, e.g. the tube 107 shown in FIG. 1. Accordingly, a decelerating electrostatic lens component can be provided in the objective lens 110. The intermediate lens 150 can be a magnetic lens. The intermediate lens 150 when having a magnetic component includes a coil 255, and an upper pole piece 254. The intermediate lens and the objective lens may share a common pole piece, such that the upper pole piece 214 of the objective lens may provide a portion of the lower pole piece of the intermediate lens 150.

A funnel 230 can be provided in the gap of the objective lens. Further, a portion of the tube 107, i.e. high potential tube 107 shown in FIG. 1, can be provided in a gap of the intermediate lens.

Shown in FIG. 2, the on-axis detector 122 has a first distance Dd from the specimen stage and the intermediate lens 150 has a second distance Di from the intermediate stage. Typically, the distance of the intermediate lens can be measured from the center of the gap between the pole pieces or, in the case of an electrostatic lens, from the middle electrode. The second distance is equal to or smaller than 50% of the first distance. Further, the second distance is ⅓ or more relative to the first distance.

According to an embodiment, a charged particle beam apparatus is provided. The charged particle beam apparatus includes a charged particle source configured to generate a primary charged particle beam. The charged particle beam apparatus further includes beam guiding objects configured to guide the primary charged particle beam towards the specimen stage and an on-axis detector having an opening configured for trespassing of the primary charged particle beam. A second detector is provided upstream of the on-axis detector. The intermediate lens is disposed between the on-axis detector and the specimen stage and is configured to collimate high energy signal electrons on the opening of the on-axis detector. The charged particle beam apparatus further includes an objective lens disposed between the intermediate lens and the specimen stage, wherein the on-axis detector has a first distance from the specimen stage and the intermediate lens has second distance from the specimen stage. The second distance is ⅓ to ½ of the first distance.

The relative arrangement between the on-axis detector, the intermediate lens and the objective lens allows for generation of a cross-over of the BSEs between the objective lens and the intermediate lens. Accordingly, the BSEs can be collimated onto the opening of the on-axis detector 122 to increase the overall detection efficiency.

As shown in FIG. 2, the charged particle beam apparatus may further include a first power supply 264. The first power supply 264 is connected to the coil 255 and may provide a current to the coil for excitation of the intermediate lens 150. The charged particle beam apparatus may further include the second power supply 266. The second power supply 266 is connected to the coil 215 and may provide a current to the coil for excitation of the objective lens 110. The first power supply 264 and the second power supply 266 can be connected to a controller 260. The controller controls the currents and voltages for operation of the objective lens 110 and the intermediate lens and allows for various modes of operation, particularly switching between operation modes as described in more detail below.

According to an embodiment, a method of operating a charged particle beam apparatus is provided. The method includes guiding a primary charged particle beam through an opening of an on-axis detector, through an intermediate lens, through an objective lens and onto a specimen wherein the intermediate lens is disposed between the on-axis detector and the objective lens. The method includes focusing the charged particle beam with the objective lens onto the specimen. In a first mode of operation, the intermediate lens is excited to collimate high energy signal electrons including backscattered electrons to the opening of the on-axis detector. Further, in the first mode of operation, low energy signal electrons including secondary electrons are detected with the on-axis detector and backscattered electrons are detected with the second electron detector upstream of the on-axis detector.

According to embodiments of the present disclosure high energy signal electrons are signal electrons (at or) above an energy threshold and low energy signal electrons are signal electrons below an energy threshold. According to some embodiments, which can be combined with other embodiments described herein, the high energy signal electrons can be at 20% or more of the landing energy of the primary charged particle beam and the low energy signal electrons can be at below 20% of the landing energy of the primary charged particle beam. According to some embodiments, which can be combined with other embodiments described herein, the high energy signal electrons can be at 30% or more of the landing energy of the primary charged particle beam and the low energy signal electrons can be at below 30% of the landing energy of the primary charged particle beam. According to some embodiments, which can be combined with other embodiments described herein, the high energy signal electrons can be at 50% or more of the landing energy of the primary charged particle beam and the low energy signal electrons can be at below 50% of the landing energy of the primary charged particle beam.

According to some embodiments, the energy threshold may be different for the first mode of operation and the second mode of operation.

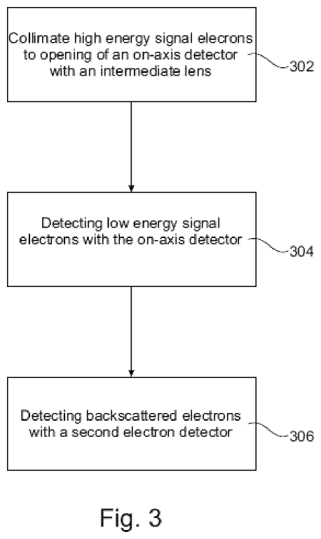

With respect to FIG. 3, a method of operating a charged particle beam apparatus includes guiding and focusing a primary charged particle beam onto the specimen. The flowchart illustrated in FIG. 3 shows a first mode of operation. At operation 302, high energy electrons are collimated to the opening of the on-axis detector. Low energy signal electrons are detected with the on-axis detector as shown by operation 304. At operation 306, backscattered electrons are detected with the second electron detector, for example an off-axis detector shown in FIG. 1.

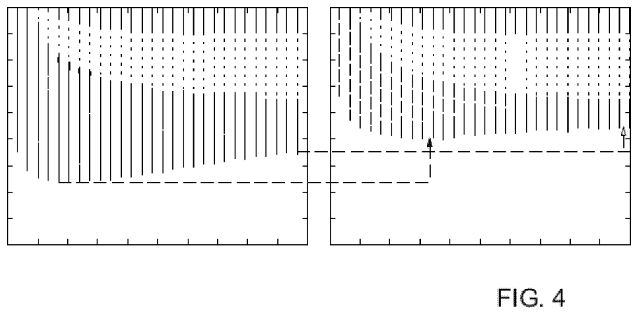

According to some embodiments, which can be combined with other embodiments described herein, the intermediate lens is excited to generate a cross-over of the high energy signal electrons between the objective lens and the intermediate lens. This is shown in FIG. 2. For example, collimated high energy signal electrons pass the high energy signal electrons with the starting angle of 30° or more through the opening of the on-axis detector. FIG. 4 shows a comparison between the situation, in which the intermediate lens is switched off, which is shown on the left-hand side and the situation, in which the intermediate lens is switched on according to the first mode of operation. FIG. 4 shows an angle distribution of signal electrons as a function of the energy. The signal electrons in the upper portion of the graphs shown in FIG. 4, i.e. signal electrons with a large starting angle (further away from the optical axis) are collected by the on-axis detector or hit portions of the charged particle beam apparatus or the wafer and are lost for detection. The white areas below the dashed lines show the signal electrons passing through the opening of the on-axis detector, which are detected by the second electron detector. As can be seen by the comparison of FIG. 4, a significant increase in signal electrons passing towards the second electron detector can be achieved.

In the first mode of operation, in which the high energy electrons, i.e. mainly backscattered electrons, are focused on the opening of the on-axis detector for detection on the second electron detector, the increase shown in FIG. 4 results in an increased collection efficiency for backscattered electrons. Embodiments of the present disclosure improve the electron detection by increasing collection efficiency to improve signal-to-noise ratio. This improves throughput. Decreasing BSE losses increases throughput for detection of medium and high landing energies.

The energy of backscattered electron depends on the energy of the landing energy of the primary electron beam. For smaller landing energy, e.g. of 2 keV or below or even 1 keV or below, the energy of the BSEs is such that a collection of signal electrons might be sufficient without an intermediate lens. Yet, an intermediate lens may further improve the collection efficiency also in this case. According to some embodiments, which can be combined with other embodiments described herein, providing an excitation of the intermediate lens can be provided for landing energies of 2 keV or more, particularly for landing energies of 2 keV to 5 keV. Further, an excitation of the intermediate lens can be provided for landing energies of 5 keV or more. For such medium or high landing energies, utilization of an intermediate lens might be particularly useful.

This signal electrons in the upper portion of the graphs shown in FIG. 4, which are for example detected by the on-axis detector 122, have a large starting angle. The signal electrons with a large starting angle provide information on the topography of the specimen, for example, a wafer. In other words, signal electrons with a large starting angle have more topographical information as compared to signal electrons with a small starting angle, for example, signal electrons emitted along the optical axis. Accordingly, according to some embodiments, which can be combined with other embodiments described herein, the on-axis detector can be a segmented detector. For example, 4 segments of a circle (each covering e.g.) 90° can be provided as segments of the on-axis detector. The on-axis detector can be a quad detector, in which directions (x-direction and y-direction in a specimen plane) of the starting angles can be independently detected.

Embodiments of the present disclosure provide a method of operating a charged particle beam, wherein the backscattered electron beam (BSE) in the scanning electron microscope are controlled. The method uses an intermediate lens (IML), for example an intermediate magnetic lens, in the vicinity of a magnetic objective lens that condenses the BSE in order to increase the overall collection, to collimate the BSE on the opening of an on-axis detector. Off-axis BSE (high polar angle) at higher landing energies are difficult to bring to the detector inside the SEM column because the BSE are hitting the other parts inside the column, and therefore are lost. According to some implementations, the IML can provide different functionalities in controlling the BSE beam. Backscattered electrons reaching the area of IML are focused by the IML and are collimated to the opening of the on-axis detector, where the BSE beam continues to the second electron detector.

Method of operating a charged particle beam apparatus according to embodiments of the present disclosure may further include adjusting the excitation of the intermediate lens to a second mode of operation. The second mode of operation includes detecting high energy signal electrons with the on-axis detector and collimating low energy signal electrons to the opening of the on-axis detector. Energy filtering can be provided to increase the signal-to noise ratio. In the second mode of operation, the intermediate lens forms a cross-over of the primary charged particle beam. In the second mode of operation, the objective lens focuses the cross-over (as compared to focusing the source and the first mode of operation). Accordingly, the excitation of the objective lens in the second mode of operation is stronger.

According to some embodiments, which can be combined with other embodiments described herein, and the second mode of operation, the excitation of the intermediate lens is higher as compared to the excitation in the first mode of operation. Additionally or alternatively, the excitation of the intermediate lens in the second mode of operation generates a cross-over of the primary charged particle beam between the intermediate lens and the objective lens. Accordingly, the excitation of the objective lens and the second mode of operation is higher as compared to the excitation in the first mode of operation.

The detection of signal electrons can be described by detection of high energy signal electrons and low energy signal electrons. Additionally or alternatively, reference can be made to detection of secondary electrons or backscattered electrons, wherein secondary electrons have an energy of up to about 50 eV and backscattered electrons have an energy of about 50 eV or above. The high energy signal electrons include BSEs and the low energy signal electrons include secondary electrons.

The energy threshold between high energy signal electrons and low energy signal electrons can be determined by absolute energy values, for example, the threshold can be at 50 eV, 200 eV, 500 eV, 1 keV, 2 keV or even 5 keV. The threshold between high energy signal electrons and low energy signal electrons can be determined relative to the landing energy of the primary charged particle beam, for example, the threshold can be at 20%, 30%, 50% or 60% of the landing energy of the primary charged particle beam. High energy signal electrons are (at or) above the threshold and low energy signal electrons are below the threshold.

The energy threshold may vary in light of the application and the measurements to be conducted, e.g. based upon the sample structure. According to some embodiments, which can be combined with other embodiments described herein, the first mode of operation may have a first energy threshold as described above and the second mode of operation may have a second threshold as described above. The first threshold and/or the second threshold may be adapted. The landing energies of the primary charged particle beam may be for example 1 keV or above, 3 keV or above, 5 keV or above or even 10 keV or above.

According to embodiments of the present disclosure, an on-axis detector is provided. For example the on-axis detector can be segmented, for example, to improve detection of topography information. The on-axis detector may typically not include an energy filter beyond the energy filtering of the different modes of operation according to embodiments of the present disclosure. According to embodiments of the present disclosure, a second electron detector, for example, an off-axis electron detector as shown in FIG. 1, is provided. The second electron detector may include an additional energy filter. According to some embodiments, the second electron detector may not provide for topographical information. Embodiments of the present disclosure providing an intermediate lens can separate low energy signal electrons, for example, secondary electrons, and high energy signal electrons, for example backscattered electrons. In the first mode of operation, the high energy signal electrons can be collimated on an opening of the on-axis detector to be detected by the second electron detector. In a second mode of operation, the high energy signal electrons can be filtered to be detected by the on-axis detector.

According to some embodiments, which can be combined with other embodiments described herein, high energy signal electrons, such as backscattered electrons, can be energy filtered and detected by a segmented detector. Accordingly, topographical information, i.e. angular information, of the backscattered electrons can be detected by the on-axis detector. In the second mode of operation, the on-axis detector detects high energy signal electrons, e.g. backscattered electrons at or above an energy threshold. Accordingly, according to some embodiments, which can be combined with other embodiments described herein, a high pass filter can be provided.

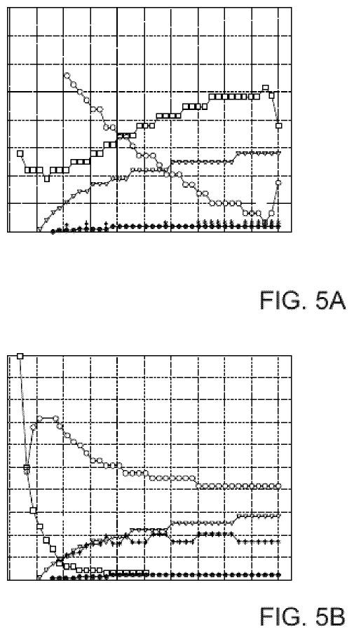

FIGS. 5A and 5B show a comparison of different modes of operation. FIG. 5A shows the first mode of operation according to embodiments of the present disclosure. The intermediate lens pre-focuses the primary charged particle beam and the objective lens can be operated at a reduced excitation level. The intermediate lens collimates the high energy signal electrons, for example, the backscattered electrons on the opening of the on-axis detector. The high energy signal electrons can be detected by the second electron detector upstream of the on-axis detector. The low energy signal electrons are detected by the on-axis detector. FIG. 5A shows the simulation of the signal count as the function of the energy of the signal electrons. The curve having the open circles shows the signal count on the on-axis detector. The curve having the open squares shows the signal count on the second electron detector. The remaining curves show the simulated signal count on various other components, for which the signal electrons are lost for generation of an image of the specimen.

According to some embodiments, which can be combined with other embodiments described herein, particularly in the second mode of operation, the energy threshold for the filtering can be adapted by changing the excitation of the intermediate lens.

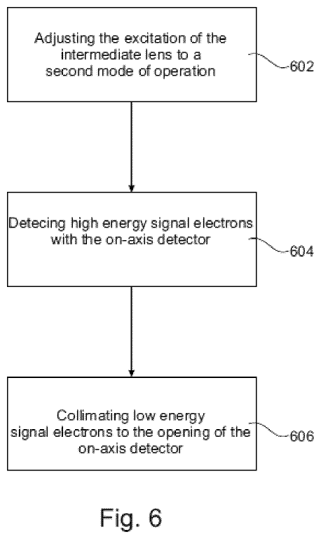

With respect to FIG. 6, a method of operating a charged particle beam apparatus includes guiding and focusing a primary charged particle beam onto the specimen. The flowchart illustrated in FIG. 6 shows the second mode of operation. At operation 602, the excitation of the intermediate lens is adjusted to operate the charged particle beam apparatus in the second mode of operation. At operation 604, high energy electrons are detected with the on-axis detector. Low energy signal electrons are collimated to the opening of the on-axis detector as shown by operation 606. According to some embodiments, which can be combined with other embodiments described herein, the low energy signal electrons, for example, secondary electrons can be detected by the second electron detector upstream of the on-axis detector.

According to various embodiments of the present disclosure, a method of operating a charged particle beam apparatus may include switching between the method illustrated in FIG. 3 and the method illustrated in FIG. 6. Switching between the different modes of operation can be provided one or more times. Yet further, it is possible to adjust the energy threshold of the energy filtering, particularly for the second mode of operation. According to some embodiments, the threshold may also be adjusted for the first mode of operation, particularly to separate SE and BSE. For example, a threshold in the first mode of operation can be set at 10 to 100 eV.

As described with respect to FIG. 1, a beam separator 124 for separating the primary charged particle beam and the signal electrons can be provided. The beam separator can be provided upstream of the on-axis detector. According to some embodiments, which can be combined with other embodiments described herein, a method of operating a charged particle beam apparatus can further include separating the primary charged particle beam from the signal electrons upstream of the on-axis detector, particularly when the second electron detector is an off-axis detector. According to some embodiments, which can be combined with other embodiments described herein, a method may further include energy filtering signa electrons between the opening of the on-axis detector and the second electron detector. Particularly, filtering may include bandpass filtering. Detection of high energy signal electrons can be improved by the combination of increasing the detection efficiency and energy filtering the signal. For example, this can be particularly advantageous for BSE energies of 1 keV or above, e.g. 10 keV or above.

According to an embodiment, a charged particle beam apparatus is provided. The charged particle beam apparatus includes a charged particle source configured to generate a primary charged particle beam. The charged particle beam apparatus further includes beam guiding objects configured to guide the primary charged particle beam towards the specimen stage and an on-axis detector having an opening configured for trespassing of the primary charged particle beam. A second detector is provided upstream of the on-axis detector. The intermediate lens is disposed between the on-axis detector and the specimen stage and is configured to collimate high energy signal electrons on the opening of the on-axis detector. The charged particle beam apparatus further includes an objective lens disposed between the intermediate lens and the specimen stage, wherein the on-axis detector has a first distance from the specimen stage and the intermediate lens has second distance from the specimen stage. The second distance is ⅓ to ½ of the first distance.

According to some embodiments, which can be combined with other embodiments described herein, the first distance of the on-X detector can be about 100 mm to 300 mm and the second distance of the intermediate lens can be about 33.3 mm to 150 mm.

Embodiments of a charged particle beam apparatus, which can be combined with other embodiments described herein, can be described with respect to FIGS. 1 and 2. As exemplarily shown in FIG. 1, the objective lens can be a combined electrostatic-magnetic objective lens. Further, the intermediate lens can be a magnetic lens. Particularly the intermediate lens can be an axial gap lens. According to some optional implementations, the objective lens and the intermediate lens can have a common pole piece.

As illustrated in FIG. 2, according to some embodiments, which can be combined with other embodiments described herein, a first distance D1 of one or more of the pole pieces of the intermediate lens from the optical axis can be larger than a second distance D2 of one or more of the pole pieces of the objective lens.

According to some embodiments, which can be combined with other embodiments described herein, a charged particle beam apparatus can include a controller with a processor and a memory storing instructions that when executed by the process, cause the apparatus to perform a method according to any of the embodiments described herein.

The controller 260 exemplarily shown in FIG. 2, controls the operation of the objective lens 110 and of the intermediate lens 150. The controller 260 comprises a central processing unit (CPU), a memory and, for example, support circuits. To facilitate control of the charged particle beam apparatus, and particularly to control the intermediate lens 150 to operate in different modes of operation, the CPU may be one of any form of general-purpose computer processor that can be used in an industrial setting for controlling various chambers and sub-processors. The memory is coupled to the CPU. The memory, or a computer readable medium, may be one or more readily available memory devices such as random-access memory, read only memory, hard disk, or any other form of digital storage either local or remote. The support circuits may be coupled to the CPU for supporting the processor in a conventional manner. The circuits include cache, power supplies, clock circuits, input/output circuitry and related subsystems, and the like. Inspecting process instructions are generally stored in the memory as a software routine typically known as a recipe. The software routine may also be stored and/or executed by a second CPU (not shown) that is remotely located from the hardware being controlled by the CPU. The software routine, when executed by the CPU, transforms the general-purpose computer into a specific purpose computer (controller) that controls the apparatus operation such as that control of backscattered electron detection and/or filtering of signal electrons can be provided. Although the method and/or process of the present disclosure is discussed as being implemented as a software routine, some of the method steps that are disclosed therein may be performed in hardware as well as by the software controller. As such, the invention may be implemented in software as executed upon a computer system, and hardware as an application specific integrated circuit or other type of hardware implementation, or a combination of software and hardware.

The controller may execute or perform a method of operating a charged particle beam apparatus, according to embodiments of the present disclosure and as exemplarily described and explained with respect to FIGS. 3 to 6.

In the present disclosure, a plurality of embodiments are described, which include inter alia the following embodiments.

Embodiment 1. A method of operating a charged particle beam apparatus, comprising: guiding a primary charged particle beam through an opening of an on-axis detector, through an intermediate lens, through an objective lens, and onto a specimen, wherein the intermediate lens is disposed between the on-axis detector and the objective lens; focusing the primary charged particle beam with the objective lens onto the specimen; in a first mode of operation, providing an excitation of the intermediate lens to collimate high energy signal electrons including backscattered electrons to the opening of the on-axis detector; in the first mode of operation, detecting low energy signal electrons including secondary electrons with the on-axis detector; and in the first mode of operation, detecting the backscattered electrons with a second electron detector upstream of the on-axis detector.

Embodiment 2. The method of embodiment 1, wherein collimating the high energy signal electrons passes high energy signal electrons with a starting angle of 30° or more through the opening of the on-axis detector.

Embodiment 3. The method of any of embodiments 1 to 2, further comprising: adjusting the excitation of the intermediate lens to a second mode of operation, comprising: detecting high energy signal electrons with the on-axis detector; and collimating low energy signal electrons to the opening of the on-axis detector.

Embodiment 4. The method of embodiment 3, wherein the excitation of the intermediate lens in the second mode of operation is higher as compared to the excitation in the first mode of operation.

Embodiment 5. The method of any of embodiments 1 to 4, further comprising: separating the primary charged particle beam from signal electrons upstream of the on-axis detector, wherein the second electron detector is an off-axis detector.

Embodiment 6. The method of any of embodiments 1 to 5, further comprising: energy filtering signal electrons between the opening of the on-axis detector and the second electron detector.

Embodiment 7. A charged particle beam apparatus, comprising: a charged particle beam source configured to generate a primary charged particle beam; beam guiding optics configured to guide the primary charged particle beam towards a specimen stage; an on-axis detector having an opening configured for trespassing of the primary charged particle beam; a second detector upstream of the on-axis detector; an intermediate lens disposed between the on-axis detector and the specimen stage and configured to collimate high energy signal electrons on the opening of the on-axis detector; an objective lens disposed between the intermediate lens and the specimen stage, and an energy filter along a signal beam path between the opening of the on-axis detector and the second detector.

Embodiment 8. The charged particle beam apparatus according to embodiment 7, further comprising: a controller with a processor and a memory storing instructions that, when executed by the processor, cause the charged particle beam apparatus to perform a method according to any of embodiments 1 to 6.

Embodiment 9. The charged particle beam apparatus according to any of embodiments 7 to 8, wherein the objective lens is a combined magnetic-electrostatic objective lens.

Embodiment 10. The charged particle beam apparatus of any of embodiments 7 to 9, wherein the intermediate lens is a magnetic lens.

Embodiment 11. The charged particle beam apparatus of embodiment 10, wherein the intermediate lens is an axial gap lens.

Embodiment 12. The charged particle beam apparatus of any of embodiments 7 to 11, wherein a first distance of the on-axis detector is about 100 mm to 300 mm and a second distance of the intermediate lens is about 33.3 mm to 150 mm.

Embodiment 13. The charged particle beam apparatus of any of embodiments 7 to 12, further comprising: a beam separator upstream of the on-axis detector.

Embodiment 14. The charged particle beam apparatus according to any of embodiments 7 to 13, wherein the objective lens and the intermediate lens have a common pole piece.

Embodiment 15. The charged particle beam apparatus according to any of embodiments 7 to 14, wherein a first distance of one or more first pole pieces of the intermediate lens from an optical axis is larger than a second distance of one or more second pole pieces of the objective lens from the optical axis.

Embodiment 16. A charged particle beam apparatus, comprising: a charged particle beam source configured to generate a primary charged particle beam; beam guiding optics configured to guide the primary charged particle beam towards a specimen stage; an on-axis detector having an opening configured for trespassing of the primary charged particle beam; a second detector upstream of the on-axis detector; an intermediate lens disposed between the on-axis detector and the specimen stage and configured to collimate high energy signal electrons on the opening of the on-axis detector; an objective lens disposed between the intermediate lens and the specimen stage, and a controller with a processor and a memory storing instructions that, when executed by the processor, cause the charged particle beam apparatus to perform a method according to any of embodiments 1 to 6.

While the foregoing is directed to embodiments, other and further embodiments may be devised without departing from the basic scope, and the scope thereof is determined by the claims that follow.

1. A method of operating a charged particle beam apparatus, comprising:
guiding a primary charged particle beam through an opening of an on-axis detector, through an intermediate lens, through an objective lens, and onto a specimen, wherein the intermediate lens is disposed between the on-axis detector and the objective lens;
focusing the primary charged particle beam with the objective lens onto the specimen;
in a first mode of operation, providing an excitation of the intermediate lens to collimate high energy signal electrons including backscattered electrons to the opening of the on-axis detector;
in the first mode of operation, detecting low energy signal electrons including secondary electrons with the on-axis detector; and
in the first mode of operation, detecting the backscattered electrons with a second electron detector upstream of the on-axis detector.

2. The method of claim 1, wherein collimating the high energy signal electrons passes high energy signal electrons with a starting angle of 30° or more through the opening of the on-axis detector.

3. The method of claim 1, further comprising:
adjusting the excitation of the intermediate lens to a second mode of operation, comprising:
detecting high energy signal electrons with the on-axis detector; and
collimating low energy signal electrons to the opening of the on-axis detector.

4. The method of claim 3, wherein the excitation of the intermediate lens in the second mode of operation is higher as compared to the excitation in the first mode of operation.

5. The method of claim 1, further comprising:
separating the primary charged particle beam from signal electrons upstream of the on-axis detector, wherein the second electron detector is an off-axis detector.

6. The method of claim 1, further comprising:
energy filtering signal electrons between the opening of the on-axis detector and the second electron detector.

7. A charged particle beam apparatus, comprising:
a charged particle beam source configured to generate a primary charged particle beam;
beam guiding optics configured to guide the primary charged particle beam towards a specimen stage;
an on-axis detector having an opening configured for trespassing of the primary charged particle beam;
a second detector upstream of the on-axis detector;
an intermediate lens disposed between the on-axis detector and the specimen stage and configured to collimate high energy signal electrons on the opening of the on-axis detector;
an objective lens disposed between the intermediate lens and the specimen stage; and
an energy filter along a signal beam path between the opening of the on-axis detector and the second detector.

8. The charged particle beam apparatus according to claim 7, further comprising:
a controller with a processor and a memory storing instructions that, when executed by the processor, cause the charged particle beam apparatus to perform a method of operating the charged particle beam apparatus, the method comprising:
guiding the primary charged particle beam through the opening of the on-axis detector, through the intermediate lens, through the objective lens, and onto a specimen, wherein the intermediate lens is disposed between the on-axis detector and the objective lens;
focusing the primary charged particle beam with the objective lens onto the specimen;
in a first mode of operation, providing an excitation of the intermediate lens to collimate high energy signal electrons including backscattered electrons to the opening of the on-axis detector;
in the first mode of operation, detecting low energy signal electrons including secondary electrons with the on-axis detector; and
in the first mode of operation, detecting the backscattered electrons with a second electron detector upstream of the on-axis detector.

9. The charged particle beam apparatus according to claim 8, wherein collimating the high energy signal electrons passes high energy signal electrons with a starting angle of 30° or more through the opening of the on-axis detector.

10. The charged particle beam apparatus according to claim 8, further comprising:
adjusting the excitation of the intermediate lens to a second mode of operation, comprising:
detecting high energy signal electrons with the on-axis detector; and
collimating low energy signal electrons to the opening of the on-axis detector.

11. The charged particle beam apparatus according to claim 7, wherein the objective lens is a combined magnetic-electrostatic objective lens.

12. The charged particle beam apparatus according to claim 7, wherein the intermediate lens is a magnetic lens.

13. The charged particle beam apparatus of claim 12, wherein the intermediate lens is an axial gap lens.

14. The charged particle beam apparatus according to claim 7, wherein a first distance of the on-axis detector is about 100 mm to 300 mm and a second distance of the intermediate lens is about 33.3 mm to 150 mm.

15. The charged particle beam apparatus according to claim 7, further comprising:
a beam separator upstream of the on-axis detector.

16. The charged particle beam apparatus according to claim 7, wherein the objective lens and the intermediate lens have a common pole piece.

17. The charged particle beam apparatus according to claim 7, wherein a first distance of one or more first pole pieces of the intermediate lens from an optical axis is larger than a second distance of one or more second pole pieces of the objective lens from the optical axis.

18. A charged particle beam apparatus, comprising:
a charged particle beam source configured to generate a primary charged particle beam;
beam guiding optics configured to guide the primary charged particle beam towards a specimen stage;
an on-axis detector having an opening configured for trespassing of the primary charged particle beam;
a second detector upstream of the on-axis detector;
an intermediate lens disposed between the on-axis detector and the specimen stage and configured to collimate high energy signal electrons on the opening of the on-axis detector;
an objective lens disposed between the intermediate lens and the specimen stage, and
a controller with a processor and a memory storing instructions that, when executed by the processor, cause the charged particle beam apparatus to perform a method of operating the charged particle beam apparatus, the method comprising:
guiding the primary charged particle beam through the opening of the on-axis detector, through the intermediate lens, through the objective lens, and onto a specimen, wherein the intermediate lens is disposed between the on-axis detector and the objective lens;
focusing the primary charged particle beam with the objective lens onto the specimen;
in a first mode of operation, providing an excitation of the intermediate lens to collimate high energy signal electrons including backscattered electrons to the opening of the on-axis detector;
in the first mode of operation, detecting low energy signal electrons including secondary electrons with the on-axis detector; and
in the first mode of operation, detecting the backscattered electrons with a second electron detector upstream of the on-axis detector.

19. The charged particle beam apparatus according to claim 18, wherein collimating the high energy signal electrons passes high energy signal electrons with a starting angle of 30° or more through the opening of the on-axis detector.

20. The charged particle beam apparatus according to claim 18, further comprising:
adjusting the excitation of the intermediate lens to a second mode of operation, comprising:
detecting high energy signal electrons with the on-axis detector; and
collimating low energy signal electrons to the opening of the on-axis detector.
